(19) United States
(12) Patent Application Publication
(10) Pub. No.: US 2024/0234428 A9
(43) Pub. Date: Jul. 11, 2024

(54) ARRAY SUBSTRATE, MANUFACTURING METHOD THEREOF, AND DISPLAY PANEL

(71) Applicant: Guangzhou China Star Optoelectronics Semiconductor Display Technology Co., Ltd, Guangzhou (CN)

(72) Inventors: Mingjiue YU, Guangzhou (CN); Zhixiong JIANG, Guangzhou (CN); Lanlan LI, Guangzhou (CN)

(73) Assignee: Guangzhou China Star Optoelectronics Semiconductor Display Technology Co., Ltd., Guangzhou (CN)

(21) Appl. No.: 18/088,801

(22) Filed: Dec. 27, 2022

(30) Foreign Application Priority Data
Oct. 19, 2022 (CN) 202211276765.9

(51) Int. Cl. H01L 27/12; H01L 29/786

(52) U.S. Cl. CPC H01L 27/1225; H01L 27/124; H01L 27/1248; H01L 27/127; H01L 27/1288; H01L 29/78633; H01L 29/7869

(57) ABSTRACT

An array substrate, a manufacturing method of the array substrate, and a display panel are provided. The array substrate includes a metal light-shielding layer, a buffer layer an active layer, an interlayer insulating layer, and a source-drain electrode layer, a plurality of first via holes are disposed in the interlayer insulating layer, the active layer includes a metal oxide body layer and an etching barrier layer disposed on a surface of the metal oxide body layer, the etching barrier layer includes a plurality of first etching barrier sections corresponding to the first via holes, and the source-drain electrode layer is electrically connected to the metal oxide body layer through the first etching barrier sections.

### FIELD OF INVENTION

The present disclosure relates to a field of display technology, and particularly relates to an array substrate, a manufacturing method of the array substrate, and a display panel.

### BACKGROUND OF INVENTION

In conventional display panels, a buffer layer and an interlayer insulating layer are disposed between a metal light-shielding layer and a source-drain electrode layer of an array substrate, and the interlayer insulating layer is disposed between an active layer and the source-drain electrode layer. The source-drain electrode layer is electrically connected to the active layer and the metal light-shielding layer respectively, and depths of two types of via holes required for the source-drain electrode layer and the metal light-shielding layer are different.

If the two types of the via holes are formed at the same time, utilizing a halftone mask is required. Compared with an ordinary mask provided with fully transparent openings, a cost of the halftone mask is higher. Therefore, a manufacturing cost of an array substrate of the conventional display panel remains high.

Therefore, there is an urgent need for an array substrate, a manufacturing method of the array substrate, and a display panel to solve the above technical problem.

### SUMMARY OF INVENTION

The present disclosure provides an array substrate, a manufacturing method of the array substrate, and a display panel, which may solve the technical problem of a high cost caused by the halftone mask, when via holes of the interlayer insulating layer and via holes of the buffer layer are formed at the same time.

The present disclosure provides an array substrate, including a substrate, a metal light-shielding layer disposed on a surface of the substrate, a buffer layer disposed on a surface of the metal light-shielding layer away from the substrate, an active layer disposed on a surface of the buffer layer away from the substrate, an interlayer insulating layer disposed on a surface of the active layer away from the substrate and provided with a plurality of first via holes, and a source-drain electrode layer disposed on a surface of the interlayer insulating layer away from the substrate and electrically connected to the active layer through the first via holes.

wherein the array substrate further includes a plurality of second via holes penetrating the interlayer insulating layer and the buffer layer, the source-drain electrode layer is electrically connected to the metal light-shielding layer through the second via holes, the active layer includes a metal oxide body layer and an etching barrier layer disposed on a surface of the metal oxide body layer away from the substrate, the etching barrier layer includes a plurality of first etching barrier sections corresponding to the first via holes, and the source-drain electrode layer is electrically connected to the metal oxide body layer through the first etching barrier sections.

Optionally, the etching barrier layer includes a plurality of metal oxide semiconductor materials doped with a zirconium element, and doping elements of the metal oxide semiconductor materials include a microcrystalline zirconia.

Optionally, the metal oxide body layer includes at least two metal oxide material layers, and metal oxide materials of two adjacent of the metal oxide material layers are different.

Optionally, the etching barrier layer further includes a plurality of second etching barrier sections, and each of the second etching barrier sections is located between two corresponding ones of the first etching barrier sections.

Optionally, a content of a zirconium element in the first etching barrier sections is greater than a content of a zirconium element in the second etching barrier sections.

Optionally, materials of the metal oxide body layer and materials of the etching barrier layer are same.

Optionally, a content of a zirconium element in the etching barrier layer is equal to or greater than a content of a zirconium element in the metal oxide body layer

Optionally, a ratio of a mass of a zirconium element in the etching barrier layer to a mass of all metal elements in the etching barrier layer ranges from 0.1% to 20%.

The present disclosure further provides a manufacturing method of an array substrate, including following steps: providing a substrate; forming a metal light-shielding layer on the substrate; forming a buffer layer on the metal light-shielding layer; forming an active layer on the buffer layer, and the active layer including a metal oxide body layer and an etching barrier layer disposed on a surface of the metal oxide body layer away from the substrate, wherein the etching barrier layer includes two first etching barrier sections disposed on a surface of the metal oxide body layer; forming an interlayer insulating layer on the active layer; patterning the interlayer insulating layer and the buffer layer to form a plurality of first via holes penetrating the interlayer insulating layer and a plurality of second via holes penetrating the interlayer insulating layer and the buffer layer; and forming a source-drain electrode layer on the interlayer insulating layer, wherein the source-drain electrode layer is electrically connected to the active layer through the first via holes, and the source-drain electrode layer is electrically connected to the metal oxide body layer through the second via holes.

Optionally, the step of patterning the interlayer insulating layer and the buffer layer includes: patterning the interlayer insulating layer and the buffer layer by a first mask, to form the plurality of first via holes penetrating the interlayer insulating layer and the plurality of second via holes penetrating the interlayer insulating layer and the buffer layer. Wherein the first mask includes a plurality of first openings and a plurality of second openings, each of the first openings corresponds to one of the first via holes, each of the second openings corresponds to one of the second via holes, and the first openings and the second openings are fully light transmissive.

Optionally, the step of forming the active layer on the buffer layer includes: forming the metal oxide body layer and the etching barrier layer on the buffer layer, wherein the etching barrier layer is disposed on the surface of the metal oxide body layer away from the substrate, the etching barrier layer includes a plurality of metal oxide semiconductor materials doped with a zirconium element, and the etching barrier layer includes the two first etching barrier sections disposed on the surface of the metal oxide body layer; and annealing the active layer for at least 30 minutes at a temperature ranging from 150° C. to 220° C. in an air, to make at least part of the zirconium element in the etching barrier layer is present in a form of a microcrystalline zirconia.

The present disclosure further provides a display panel, including any of the above array substrate.

Beneficial effects of the present disclosure: in the display device of the present disclosure, since the first etching barrier sections of the etching barrier layer is provided at a position corresponding to the first via holes connecting the active layer and the source-drain electrode layer, the active layer is protected by the first etching barrier sections of the etching barrier layer when forming via holes in the interlayer insulating layer and via holes in the buffer layer by an ordinary mask provided with fully transparent openings. Thereby, an etching effect on the active layer is reduced, and at the same time, by continuing to etch the buffer layer to form the second via holes corresponding to the metal light-shielding layer, the metal light-shielding layer can be exposed. Not only two types of the via holes are formed at one time, but also the active layer is protected, which ensures electrical stability of the active layer, saves process steps, and reduces costs of photomasks.

### DESCRIPTION OF DRAWINGS

FIG. 1 is a schematic view of an array substrate according to an embodiment of the present disclosure.

FIG. 2 is an enlarged schematic view of a first kind of structure of an area A in the FIG. 1.

FIG. 3 is an enlarged schematic view of a second kind of structure of an area A in the FIG. 1.

FIG. 4 is an enlarged schematic view of a third kind of structure of an area A in the FIG. 1.

FIG. 5 is an enlarged schematic view of a forth kind of structure of an area A in the FIG. 1.

FIG. 6 is an enlarged schematic view of a fifth kind of structure of an area A in the FIG. 1.

FIG. 7 is an enlarged schematic view of a sixth kind of structure of an area A in the FIG. 1.

FIG. 8 is an enlarged schematic view of a seventh kind of structure of an area A in the FIG. 1.

FIG. 9 is a flowchart of a manufacturing method of the array substrate according to an embodiment of the present disclosure.

FIG. 10A to FIG. 10C are schematic views of the manufacturing method of the array substrate according to an embodiment of the present disclosure.

FIG. 11 is a schematic view of a display panel according to an embodiment of the present disclosure.

FIG. 12 is a schematic view of a display device according to an embodiment of the present disclosure.

### DETAILED DESCRIPTION OF EMBODIMENTS

Technical solutions in embodiments of the present disclosure will be clearly and completely described below in conjunction with the drawings. Apparently, the described embodiments are only some of the embodiments of the present disclosure, rather than all the embodiments. Based on the embodiments of the present disclosure, all other embodiments obtained by those skilled in the art without making creative efforts should belong to the scope of protection of this application. In addition, it should be understood that the specific implementations described herein are only used to illustrate and explain the present disclosure, and are not intended to limit the present disclosure. In the present disclosure, unless otherwise stated, the used orientation words such as “up” and “down” generally refer to the upside and the downside of devices in actual use or working state, specifically as those directions shown in the drawings. And “inside” and “outside” refer to the outline of the devices.

In conventional display panels, a buffer layer and an interlayer insulating layer are disposed between a metal light-shielding layer and a source-drain electrode layer of an array substrate, and the interlayer insulating layer is disposed between an active layer and the source-drain electrode layer. The source-drain electrode layer is electrically connected to the active layer and the metal light-shielding layer respectively, and depths of two types of via holes required for the source-drain electrode layer and the metal light-shielding layer are different. If the two types of the via holes are formed at the same time, utilizing a halftone mask is required at present. Compared with an ordinary mask provided with fully transparent openings, a cost of the halftone mask is higher. Therefore, a manufacturing cost of an array substrate of the conventional display panel remains high.

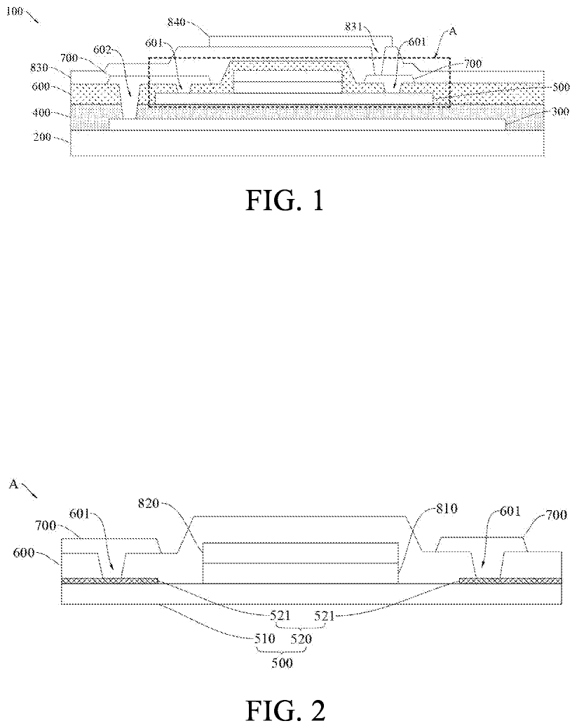

Referring to FIG. 1 to FIG. 8, The present disclosure provides an array substrate. The array substrate includes a substrate 200, a metal light-shielding layer 300, a buffer layer 400, an active layer 500, an interlayer insulating layer 600, and a source-drain electrode layer 700. A metal light-shielding layer 300 is disposed on a surface of the substrate 200, a buffer layer 400 is disposed on a surface of the metal light-shielding layer 300 away from the substrate 200, an active layer 500 is disposed on a surface of the buffer layer 400 away from the substrate 200, an interlayer insulating layer 600 is disposed on a surface of the active layer 500 away from the substrate 200 and provided with a plurality of first via holes 601, a source-drain electrode layer 700 is disposed on a surface of the interlayer insulating layer 600 away from the substrate 200, and the source-drain electrode layer 700 is electrically connected to the active layer 500 through the first via holes 601.

Wherein, the array substrate 100 further includes a plurality of second via holes 602 penetrating the interlayer insulating layer 600 and the buffer layer 400, the source-drain electrode layer 700 is electrically connected to the metal light-shielding layer 300 through the second via holes 602, the active layer 500 includes a metal oxide body layer 510 and an etching barrier layer 520 disposed on a surface of the metal oxide body layer 510 away from the substrate 200, the etching barrier layer 520 includes a plurality of first etching barrier sections 521 corresponding to the first via holes 601, and the source-drain electrode layer 700 is electrically connected to the metal oxide body layer 510 through the first etching barrier sections 521.

In the present disclosure, since the first etching barrier sections 521 of the etching barrier layer 520 is provided at a position corresponding to the first via holes 601 connecting the active layer 500 and the source-drain electrode layer 700, the active layer 500 is protected by the first etching barrier sections 521 of the etching barrier layer 520 when forming via holes in the interlayer insulating layer 600 and via holes in the buffer layer 400 by an ordinary mask provided with fully transparent openings. Thereby, an etching effect on the active layer 500 is reduced, and at the same time, by continuing to etch the buffer layer 400 to form the second via holes 602 corresponding to the metal light-shielding layer 300, the metal light-shielding layer 300 can be exposed. Two types of the via holes are formed at one time, the active layer 500 is protected, electrical stability of the active layer 500 is ensured, process steps are saved, and costs of photomasks are reduced.

Technical solutions of the present disclosure will be described in conjunction with specific embodiments.

In some embodiments, the etching barrier layer 520 includes a plurality of metal oxide semiconductor materials doped with a zirconium element, and the zirconium element of the etching barrier layer 520 include a microcrystalline zirconia.

Doping zirconium in the metal oxide semiconductor materials, and after annealing, the microcrystalline zirconia will be formed. When making holes in the interlayer insulating layer 600, the microcrystalline zirconia can reduce an etching rate, thereby reducing an etching effect on the active layer 500. The first via holes 601 are terminated at the etching barrier layer 520, and the etching is continued until the metal light-shielding layer 300 is exposed to form the second via holes. Two types of the via holes are formed at one time, the active layer is protected, electrical stability of the active layer is ensured, process steps are saved, and costs of photomasks are reduced.

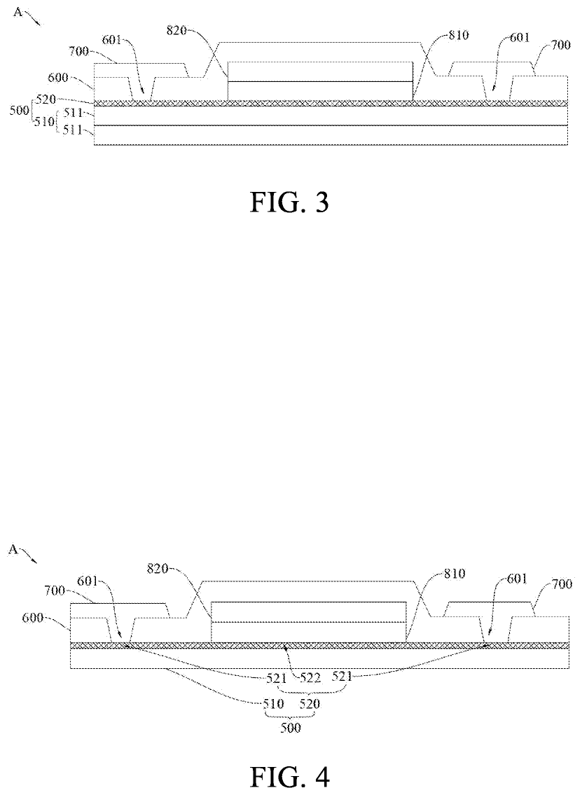

Referring to FIG. 3, in some embodiments, the metal oxide body layer 510 includes a metal oxide material layer 511.

In some embodiments, metal oxide semiconductor materials of the metal oxide body layer 510 and the etching barrier layer 520 include at least one of an indium gallium zinc oxide (IGZO), an indium gallium tin oxide (IGTO), an indium gallium oxide (IGO), or an indium zinc oxide (IZO), which are just examples, and should not be considered as any limitations to the present disclosure.

In some embodiments, the metal oxide body layer 510 includes at least two metal oxide material layers 511, and metal oxide materials of two adjacent of the metal oxide material layers 511 are different.

According to different metal oxide materials of the metal oxide material layers 511, a variety of carrier mobility film layers can be compounded to meet different product requirements. For example, in a direction from the buffer layer 400 to the interlayer insulating layer 600, a carrier mobility in the metal oxide material layers 511 gradually increases, or in the direction from the buffer layer 400 to the interlayer insulating layer 600, the carrier mobility in the metal oxide material layers 511 gradually decreases, so as to adapt to performance requirements of different array substrates 100 and improve product competitiveness.

Referring to FIG. 3, in some embodiments, the etching barrier layer 520 covers all the metal oxide body layers 510.

Referring to FIG. 4, in some embodiments, the etching barrier layer 520 further includes a plurality of second etching barrier sections 522, and each of the second etching barrier sections 522 is located between two corresponding ones of the first etching barrier sections 521.

Referring to FIG. 6, the active layer 500 includes conductor regions 501 and a channel region 502, the conductor regions 501 are located at both side of the active layer 200, and the channel region 502 is located between two corresponding conductor regions 501. The first etching barrier section 521 corresponds to the conductor region 501, and the second etching barrier section 522 corresponds to the channel region 502. When conducting the active layer 500, the conductive regions 501 that needs to be conducted is generally bombarded by plasmas, so as to form oxygen holes in the first etching sections 521. The oxygen holes have a diffusion effect, and after being bombarded by ions, the microcrystalline zirconia is less damaged, which can reduce a diffusion of the oxygen holes, conductive parts of the active layer 500 can be controlled precisely. For example, a length of a designed channel is 4 microns, and a diffusion error of the oxygen holes will be smaller, so that a more precise short channel can be obtained.

Referring to FIG. 6, in some embodiments, the active layer 500 includes conductor segments 5011 corresponding to the conductive regions 501 and a channel segment 5021 corresponding to the channel region 502. By the technical solutions of the present disclosure, a length of the channel segment 5021 ranges from 2 microns to 4 microns, preferably 2 microns to 3 microns. A short channel of the channel segment 5021 can make a smaller footprint of a thin film transistor, thereby more dense pixels can be set, and a display pixel density can be increased.

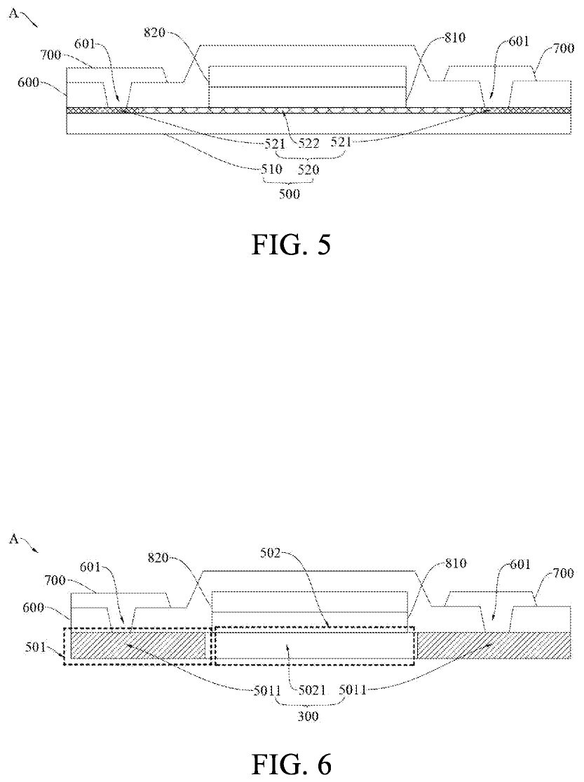

Referring to FIG. 5, in some embodiments, a content of a zirconium element in the first etching barrier sections 521 is greater than a content of a zirconium element in the second etching barrier sections 522.

The content of the zirconium element is more, and a content of the microcrystalline zirconia is more, such that an etching resistance of the first etching barrier sections 521 can be improved, and the active layer 500 can be better protected.

In some embodiments, the content of the zirconium element in the first etching barrier sections 521 is less than the content of the zirconium element in the second etching barrier sections 522.

The content of the zirconium element is more, and the content of the microcrystalline zirconia is more, such that an ability of the second etching barrier sections 522 to resist ion bombardment can be improved, a degree of a damage is less. And it is more conducive to reducing the diffusion of the oxygen holes, so that conductive parts of the active layer 500 can be controlled precisely, and a more precise short channel can be obtained.

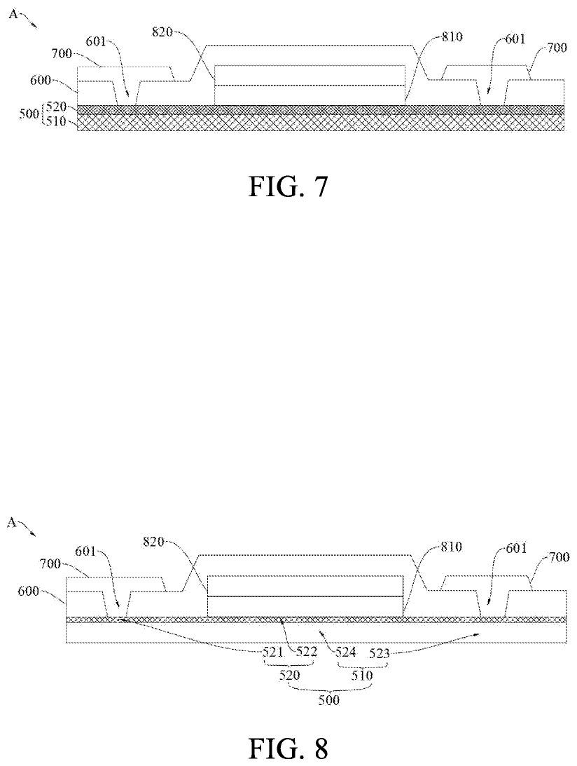

Referring to FIG. 7, in some embodiments, materials of the metal oxide body layer 510 and materials of the etching barrier layer 520 are same.

The materials of the metal oxide body layer 510 and the materials of the etching barrier layer 520 are same, which may further reduce the diffusion of the oxygen holes in the metal oxide body layer 510. So that the conductive parts of the active layer 500 can be controlled precisely, and the more precise short channel can be obtained.

In some embodiments, the metal oxide body layer 510 and the etching barrier layer 520 may be deposited together to form the active layer 500.

Referring to FIG. 7, in some embodiments, a content of a zirconium element in the etching barrier layer 520 is equal to or greater than a content of a zirconium element in the metal oxide body layer 510.

The content of a zirconium element in the metal oxide body layer 510 should not be too large, otherwise a resistivity of the metal oxide body layer 510 will increase, thereby affecting semiconductor properties of the active layer 500.

In some embodiments, a ratio of a mass of a zirconium element in the etching barrier layer 520 to a mass of all metal elements in the etching barrier layer 520 ranges from 0.1% to 20%.

The ratio of a mass of a zirconium element in the etching barrier layer 520 to a mass of all metal elements in the etching barrier layer 520 should not be high, otherwise the semiconductor properties of the active layer 500 will decrease, resistivity of the metal oxide body layer 510 will increase, which will affect the electrical properties of the active layer 500.

Referring to FIG. 8, in some embodiments, the metal oxide body layer 510 includes a plurality of first sections 523 and a plurality of second sections 524, the first sections 523 correspond to the first etching barrier sections 521, the second sections 524 correspond to the second etching barrier sections 522.

In some embodiments, referring to FIG. 6 and FIG. 8, the conductor segments 5011 includes the first etching barrier sections 521 and the first sections 523, and the channel segment 5021 includes the second etching barrier sections 522 and the second sections 524.

In some embodiments, an oxygen hole content in the first etching barrier sections 521 is greater than an oxygen hole content in the second etching barrier sections 522, and an oxygen hole content in the first sections 523 is greater than an oxygen hole content in the second sections 524.

Referring to FIG. 2, in some embodiments, the array substrate 100 further includes a gate insulating layer 810 and a gate electrode layer 820. The gate insulating layer 810 is disposed on a surface of the active layer 500 away from the substrate 200, the gate electrode layer 820 is disposed on a surface of the gate insulating layer 810 away from the active layer 500, and the gate insulating layer 810 and the gate electrode layer 820 is located between the active layer 500 and the interlayer insulating layer 600.

In some embodiments, the source-drain electrode layer 700 includes a source electrode and a drain electrode, and the source electrode is electrically connected to the metal light-shielding layer 300 through a corresponding one of the second via holes 602.

The metal light-shielding layer 300 includes a plurality of light-shielding units, an orthographic projection of the active layer 500 on the metal light-shielding layer 300 is located in the light-shielding units. The source electrode is electrically connected to the metal light-shielding layer 300, which can improve an electrical stability of the array substrate 100.

Referring to FIG. 1 and FIG. 2, in some embodiments, the array substrate 100 further includes a passivation layer 830 and a pixel electrode layer 840, a passivation layer 830 is disposed on a surface of the source-drain electrode layer 700 away from the active layer 500, and the pixel electrode layer 840 is disposed on a surface of the passivation layer 830 away from the source-drain electrode layer 700.

The passivation layer 830 includes a plurality of third via holes 831, and the pixel electrode layer 840 is electrically connected to the drain electrode of the source-drain electrode layer 700. If the array substrate 100 refers to a part of a liquid crystal display panel 10, the pixel electrode layer 840 may refer to pixel electrodes. If the array substrate 100 refers to a part of an active light-emitting display panel 10, the pixel electrode layer 840 may refer to anodes.

In some embodiments, the metal light-shielding layer 300 includes a plurality of wires, and the wires may refer to source-drain wires of the source-drain electrode layer 700.

In some embodiments, the etching barrier layer includes a plurality of metal oxide semiconductor materials doped with a zirconium element, and doping elements of the metal oxide semiconductor materials includes a microcrystalline zirconia. The microcrystalline zirconia can prevent etching to the active layer 500. When bombarded by the ions, the active layer 500 is less damaged. And it can reduce the diffusion the oxygen holes, the conductive parts of the active layer 500 can be controlled precisely, and the more precise short channel can be obtained.

In some embodiments, a thickness of the etching barrier layer 520 ranges from 100 Å to 500 Å. The thickness of the etching barrier layer 520 should not be too thick, otherwise a resistivity will increase, which may affect the semiconductor properties of the active layer 500.

In the present disclosure, since the first etching barrier sections 521 of the etching barrier layer 520 is provided at the position corresponding to the first via holes 601 connecting the active layer 500 and the source-drain electrode layer 700, the active layer 500 is protected by the first etching barrier sections 521 of the etching barrier layer 520 when forming via holes in the interlayer insulating layer 600 and via holes in the buffer layer 400 by an ordinary mask provided with fully transparent openings. Thereby, the etching effect on the active layer 500 is reduced, and at the same time, by continuing to etch the buffer layer 400 to form the second via holes 602 corresponding to the metal light-shielding layer 300, the metal light-shielding layer 300 can be exposed. The two types of the via holes are formed at one time, the active layer 500 is protected, electrical stability of the active layer 500 is ensured, the process steps are saved, and the costs of photomasks are reduced.

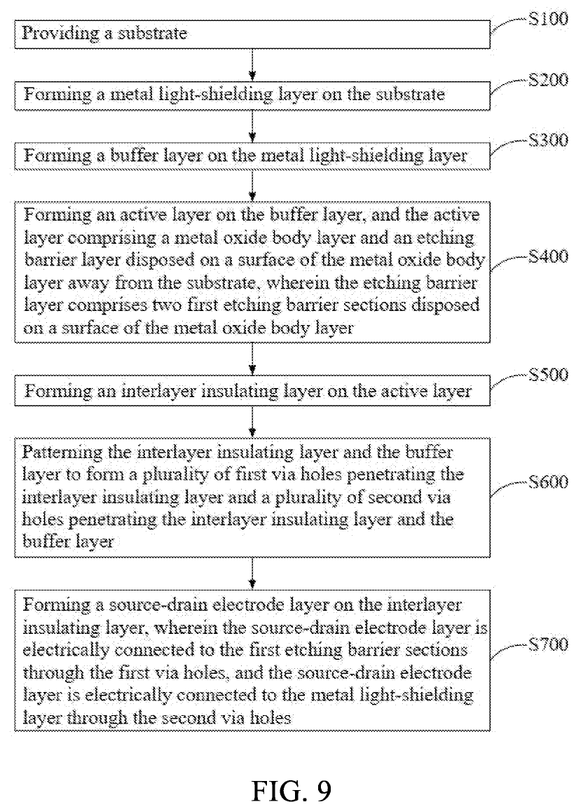

Referring to FIG. 9, the present disclosure further provides a manufacturing method of the array substrate. The manufacturing method includes following steps:

S100, providing a substrate 200.

S200, forming a metal light-shielding layer 300 on the substrate 200.

S300, forming a buffer layer 400 on the metal light-shielding layer 300.

S400, forming an active layer 500 on the buffer layer 400, and the active layer 500 including a metal oxide body layer 510 and an etching barrier layer 520 disposed on a surface of the metal oxide body layer 510 away from the substrate 200, wherein the etching barrier layer 520 includes two first etching barrier sections 521 disposed on a surface of the metal oxide body layer 510.

S500, forming an interlayer insulating layer 600 on the active layer 500.

S600, patterning the interlayer insulating layer 600 and the buffer layer 400 to form a plurality of first via holes 601 penetrating the interlayer insulating layer 600 and a plurality of second via holes 602 penetrating the interlayer insulating layer 600 and the buffer layer 400.

S700, forming a source-drain electrode layer 700 on the interlayer insulating layer 600, wherein the source-drain electrode layer 700 is electrically connected to the first etching barrier sections 521 through the first via holes 601, and the source-drain electrode layer 700 is electrically connected to the metal light-shielding layer 300 through the second via holes 602.

In the present disclosure, since the first etching barrier sections 521 of the etching barrier layer 520 is provided at the position corresponding to the first via holes 601 connecting the active layer 500 and the source-drain electrode layer 700, the active layer 500 is protected by the first etching barrier sections 521 of the etching barrier layer 520 when forming via holes in the interlayer insulating layer 600 and via holes in the buffer layer 400 by an ordinary mask provided with fully transparent openings. Thereby, the etching effect on the active layer 500 is reduced, and at the same time, by continuing to etch the buffer layer 400 to form the second via holes 602 corresponding to the metal light-shielding layer 300, the metal light-shielding layer 300 can be exposed. The two types of the via holes are formed at one time, the active layer 500 is protected, electrical stability of the active layer 500 is ensured, the process steps are saved, and the costs of photomasks are reduced.

Technical solutions of the present disclosure will be described in conjunction with specific embodiments.

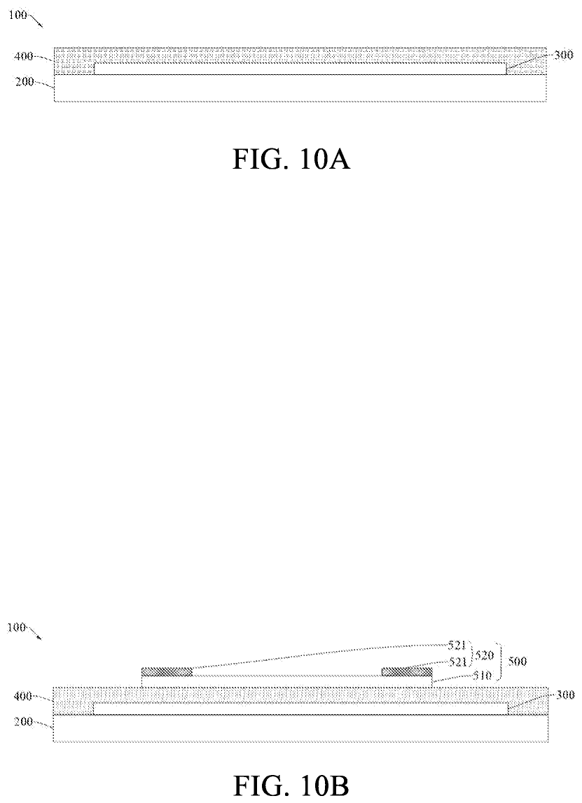

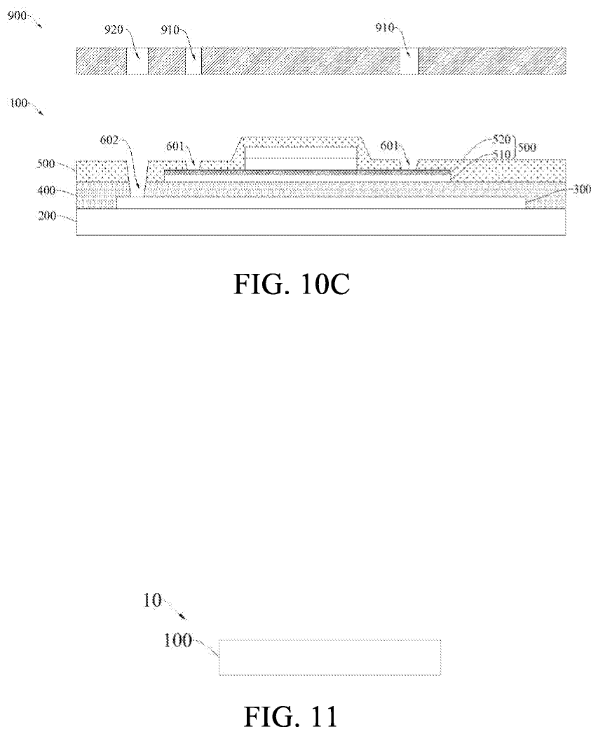

In some embodiments, the manufacturing method includes: S100, providing a substrate 200, referring to FIG. 10A.

In some embodiments, the substrate 200 refers to a glass substrate 200 or a flexible substrate 200, and the flexible substrate 200 refers to a polyimide material.

S200, forming a metal light-shielding layer 300 on the substrate 200, referring to FIG. 10A.

In some embodiments, the metal light-shielding layer 300 includes a plurality of light-shielding units, an orthographic projection of the active layer 500 on the metal light-shielding layer 300 is located in the light-shielding units. The source electrode is electrically connected to the metal light-shielding layer 300, which can improve an electrical stability of the array substrate 100.

In some embodiments, the metal light-shielding layer 300 includes a plurality of wires, and the wires can refer to source-drain wires of the source-drain electrode layer 700.

S300, forming a buffer layer 400 on the metal light-shielding layer 300, referring to FIG. 10A.

In some embodiments, materials of the buffer layer 400 may refer to a silicon oxide compound or/and a silicon nitride compound.

In some embodiments, the buffer layer 400 is set as a whole layer.

S400, forming an active layer 500 on the buffer layer 400, and the active layer 500 including a metal oxide body layer 510 and an etching barrier layer 520 disposed on a surface of the metal oxide body layer 510 away from the substrate 200, wherein the etching barrier layer 520 includes two first etching barrier sections 521 disposed on a surface of the metal oxide body layer 510, referring to FIG. 10B.

In the present disclosure, since the first etching barrier sections 521 of the etching barrier layer 520 is provided at the position corresponding to the first via holes 601 connecting the active layer 500 and the source-drain electrode layer 700, the active layer 500 is protected by the first etching barrier sections 521 of the etching barrier layer 520 when forming via holes in the interlayer insulating layer 600 and via holes in the buffer layer 400 by an ordinary mask provided with fully transparent openings. Thereby, the etching effect on the active layer 500 is reduced, and at the same time, by continuing to etch the buffer layer 400 to form the second via holes 602 corresponding to the metal light-shielding layer 300, the metal light-shielding layer 300 can be exposed. The two types of the via holes are formed at one time, the active layer 500 is protected, electrical stability of the active layer 500 is ensured, the process steps are saved, and the costs of photomasks are reduced.

In some embodiments, the step S400 includes: S410, forming the metal oxide body layer 510 and the etching barrier layer 520 on the buffer layer 400, wherein the etching barrier layer 520 is disposed on the surface of the metal oxide body layer 510 away from the substrate 200, the etching barrier layer 520 includes a plurality of metal oxide semiconductor materials doped with a zirconium element, and the etching barrier layer 520 includes the two first etching barrier sections 521 disposed on the surface of the metal oxide body layer 510; S420, annealing the active layer 500 for at least 30 minutes at a temperature ranging from 150° C. to 220° C. in an air, to make at least part of the zirconium element in the etching barrier layer 520 is present in a form of a microcrystalline zirconia; S430, conducting the active layer 500 to form conductor regions 501 at both sides of the active layer 500 and a channel region 502 between two of the conductor regions 501, referring to FIG. 6.

In some embodiments, the active layer 500 includes conductor regions 501 and a channel region 502, the conductor regions 501 are located at both side of the active layer 200, and the channel region 502 is located between two corresponding conductor regions 501. The first etching barrier section 521 corresponds to the conductor region 501, and the second etching barrier section 522 corresponds to the channel region 502. When conducting the active layer 500, the conductive regions 501 that needs to be conducted is generally bombarded by a plasma, so as to form oxygen holes in the first etching sections 521. The oxygen holes have a diffusion effect, and after being bombarded by ions, the microcrystalline zirconia is less damaged, which can reduce a diffusion of the oxygen holes, conductive parts of the active layer 500 can be controlled precisely. For example, a length of a designed channel is 4 microns, and a diffusion error of the oxygen holes will be smaller, so that a more precise short channel can be obtained.

In some embodiments, the etching barrier layer 520 further includes a plurality of second etching barrier sections 522, and each of the second etching barrier sections 522 is located between two corresponding ones of the first etching barrier sections 521.

In some embodiments, referring to FIG. 4, a content of a zirconium element in the first etching barrier sections 521 is greater than a content of a zirconium element in the second etching barrier sections 522.

In some embodiments, referring to FIG. 5, a content of a zirconium element in the first etching barrier sections 521 is less than a content of a zirconium element in the second etching barrier sections 522.

In some embodiments, referring to FIG. 7, materials of the metal oxide body layer 510 and materials of the etching barrier layer 520 are same.

In some embodiments, referring to FIG. 7, a content of a zirconium element in the etching barrier layer 520 is equal to or greater than a content of a zirconium element in the metal oxide body layer 510.

In some embodiments, a ratio of a mass of a zirconium element in the etching barrier layer 520 to a mass of all metal elements in the etching barrier layer 520 ranges from 0.1% to 20%.

In some embodiments, referring to FIG. 8, the metal oxide body layer 510 includes a plurality of first sections 523 and a plurality of second sections 524, the first sections 523 correspond to the first etching barrier sections 521, the second sections 524 correspond to the second etching barrier sections 522.

In some embodiments, referring to FIG. 6 and FIG. 8, the conductor segments 5011 includes the first etching barrier sections 521 and the first sections 523, and the channel segment 5021 includes the second etching barrier sections 522 and the second sections 524.

In some embodiments, an oxygen hole content in the first etching barrier sections 521 is greater than an oxygen hole content in the second etching barrier sections 522, and an oxygen hole content in the first sections 523 is greater than an oxygen hole content in the second sections 524.

In some embodiments, referring to FIG. 3, the metal oxide body layer 510 includes a metal oxide material layer 511.

In some embodiments, metal oxide semiconductor materials of the metal oxide body layer 510 and the etching barrier layer 520 include at least one of an IGZO, an IGTO, an IGO, or an IZO, which are just examples, and should not be considered as any limitation to the present disclosure.

In some embodiments, the metal oxide body layer 510 includes at least two metal oxide material layers 511, and metal oxide materials of two adjacent of the metal oxide material layers 511 are different.

In some embodiments, after the step S400, the manufacturing method further includes:

S401, forming a gate insulating layer 810 on the active layer 500, referring to FIG. 2.

S402, forming a gate electrode layer 820 on the gate insulating layer 810, referring to FIG. 2.

S500, forming an interlayer insulating layer 600 on the active layer 500, referring to FIG. 10C.

In some embodiments, materials of the interlayer insulating layer 600 may refer to a silicon oxide compound or/and a silicon nitride compound.

In some embodiments, the interlayer insulating layer 600 is set as a whole layer, referring to FIG. 10C.

S600, patterning the interlayer insulating layer 600 and the buffer layer 400 to form a plurality of first via holes 601 penetrating the interlayer insulating layer 600 and a plurality of second via holes 602 penetrating the interlayer insulating layer 600 and the buffer layer 400, referring to FIG. 10C.

In some embodiments, the step S600 includes:

S610, patterning the interlayer insulating layer 600 and the buffer layer 400 by a first mask 900, to form the plurality of first via holes 601 penetrating the interlayer insulating layer 600 and the plurality of second via holes 602 penetrating the interlayer insulating layer 600 and the buffer layer 400.

S620, wherein the first mask includes a plurality of first openings 910 and a plurality of second openings 920, each of the first openings 910 corresponds to one of the first via holes 601, each of the second openings 920 corresponds to one of the second via holes 602, and the first openings 910 and the second openings 920 are fully light transmissive.

When forming via holes in the interlayer insulating layer 600 and via holes in the buffer layer 400 by etching the insulating layer 600 and the buffer layer 400 with an ordinary mask provided with fully transparent openings, the active layer 520 is protected by the first etching barrier sections 521 of the etching barrier layer 520. Thereby, an etching effect on the active layer 500 is reduced, and at the same time, by continuing to etch the buffer layer 400 to form the second via holes 602 corresponding to the metal light-shielding layer 300, the metal light-shielding layer 300 can be exposed. Two types of the via holes are formed at one time, the active layer 500 is protected, electrical stability of the active layer 500 is ensured, process steps are saved, and costs of photomasks are reduced.

In some embodiments, when etching (patterning) the insulating layer 600 and the buffer layer 400, an etching material may refer to a fluorine-based gas, such as CF₄, etc.

S700, forming a source-drain electrode layer 700 on the interlayer insulating layer 600, wherein the source-drain electrode layer 700 is electrically connected to the first etching barrier sections 521 through the first via holes 601, and the source-drain electrode layer 700 is electrically connected to the metal light-shielding layer 300 through the second via holes 602, referring to FIG. 1.

In some embodiments, the source-drain electrode layer 700 includes a source electrode and a drain electrode, and the source electrode is electrically connected to the metal light-shielding layer 300 through a corresponding one of the second via holes 602.

In some embodiments, the manufacturing method further includes:

S800, forming a passivation layer 830 on the source-drain electrode layer 700, referring to FIG. 1.

In some embodiments, the step S800 includes: S810, forming the passivation layer 830 including a plurality of third via holes 831, referring to FIG. 1.

In some embodiments, the third via holes 831 penetrates the passivation layer 830, to expose the source-drain electrode layer 700.

In some embodiments, the third via holes 831 penetrates the passivation layer 830, to expose the drain electrode of the source-drain electrode layer 700.

S900, forming a pixel electrode layer 840 on the passivation layer 830, referring to FIG. 1.

In some embodiments, the pixel electrode layer 840 is electrically connected to the drain electrode of the source-drain electrode layer 700.

In the present disclosure, Since the first etching barrier sections of the etching barrier layer is provided at a position corresponding to the first via holes connecting the active layer and the source-drain electrode layer, the active layer is protected by the first etching barrier sections of the etching barrier layer when forming via holes in the interlayer insulating layer and via holes in the buffer layer by an ordinary mask provided with fully transparent openings. Thereby, an etching effect on the active layer is reduced, and at the same time, by continuing to etch the buffer layer to form the second via holes corresponding to the metal light-shielding layer, the metal light-shielding layer can be exposed. Two types of the via holes are formed at one time, the active layer is protected, electrical stability of the active layer is ensured, process steps are saved, and costs of photomasks are reduced.

Referring to FIG. 11, the present disclosure provides a display panel 10, and the display panel include any one of the above array substrates 100.

In some embodiments, the display panel 10 may refer to a liquid crystal display panel 10, and the display panel 10 further includes a liquid crystal layer, color filter layer, upper polarizing layer, and lower polarizing layer. The display panel 10 further includes a backlight unit.

In some embodiments, the display panel 10 an active light-emitting display panel 10, the display panel 10 further light-emitting device layer.

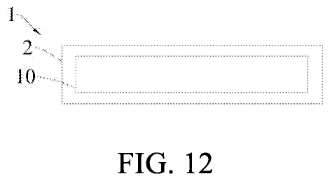

Referring to FIG. 12, the present disclosure further provides a display device 1, including any one of the above display panels 10 and a device body 2, and the device body 2 is integrated with the display panel 10.

Specific structure of the display panel 10 can refer to any one of the embodiments and the drawings of the above display panels 10, and will not be repeated here.

In an embodiment, the device body 2 may include a middle frame, a frame glue, etc., and the display device 1 may refer to a display terminal such as a mobile phone, a table, a TV, etc., which should not be considered as any limitations to the present disclosure.

The present disclosure provides an array substrate, a manufacturing method of the array substrate, and a display panel. The array substrate includes a metal light-shielding layer, a buffer layer, an active layer, an interlayer insulating layer, and a source-drain electrode layer. A plurality of first via holes are disposed in the interlayer insulating layer, and the array substrate further includes a plurality of second via holes penetrating the interlayer insulating layer and the buffer layer. The active layer includes a metal oxide body layer and an etching barrier layer disposed on a surface of the metal oxide body layer away from the substrate, the etching barrier layer includes a plurality of first etching barrier sections corresponding to the first via holes, and the source-drain electrode layer is electrically connected to the metal oxide body layer through the first etching barrier sections. In the present disclosure, when forming via holes in the interlayer insulating layer and via holes in the buffer layer by an ordinary mask provided with fully transparent openings, the active layer is protected by the first etching barrier sections of the etching barrier layer disposed on the active layer. Thereby, an etching effect on the active layer is reduced, and at the same time, by continuing to etch the buffer layer to form the second via holes, two types of the via holes are formed at one time, the active layer is protected, and costs of photomasks are reduced.

The above is a detailed introduction of an array substrate, a manufacturing method of the array substrate, and a display panel provided by the embodiments of the present disclosure. In this paper, specific examples are used to illustrate the principles and implementation methods of the present disclosure. The description of the above embodiments is only used to help understand the method and core idea of the present disclosure. At the same time, for those skilled in the art, according to the idea of the present disclosure, there will be changes in the specific implementation and application scope. In summary, the content of the specification should not be understood as a limitation on the present disclosure.

What is claimed is:

1. An array substrate, comprising:
a substrate;
a metal light-shielding layer disposed on a surface of the substrate;
a buffer layer disposed on a surface of the metal light-shielding layer away from the substrate;
an active layer disposed on a surface of the buffer layer away from the substrate;
an interlayer insulating layer disposed on a surface of the active layer away from the substrate and provided with a plurality of first via holes; and
a source-drain electrode layer disposed on a surface of the interlayer insulating layer away from the substrate and electrically connected to the active layer through the first via holes;
wherein the array substrate further comprises a plurality of second via holes penetrating the interlayer insulating layer and the buffer layer, the source-drain electrode layer is electrically connected to the metal light-shielding layer through the second via holes, the active layer comprises a metal oxide body layer and an etching barrier layer disposed on a surface of the metal oxide body layer away from the substrate, the etching barrier layer comprises a plurality of first etching barrier sections corresponding to the first via holes, and the source-drain electrode layer is electrically connected to the metal oxide body layer through the first etching barrier sections.

2. The array substrate in claim 1, wherein the etching barrier layer comprises a plurality of metal oxide semiconductor materials doped with a zirconium element.

3. The array substrate in claim 2, wherein doping elements of the metal oxide semiconductor materials comprise a microcrystalline zirconia.

4. The array substrate in claim 3, wherein the metal oxide semiconductor materials comprise at least one of an indium gallium zinc oxide (IGZO), an indium gallium tin oxide (IGTO), an indium gallium oxide (IGO), or an indium zinc oxide (IZO).

5. The array substrate in claim 2, wherein the metal oxide body layer comprises at least two metal oxide material layers, and metal oxide materials of two adjacent of the metal oxide material layers are different.

6. The array substrate in claim 2, wherein the etching barrier layer covers the metal oxide body layer.

7. The array substrate in claim 2, wherein the etching barrier layer further comprises a plurality of second etching barrier sections, and each of the second etching barrier sections is located between two corresponding ones of the first etching barrier sections.

8. The array substrate in claim 7, wherein a content of a zirconium element in the first etching barrier sections is greater than a content of a zirconium element in the second etching barrier sections.

9. The array substrate in claim 7, wherein a content of a zirconium element in the first etching barrier sections is less than a content of a zirconium element in the second etching barrier sections.

10. The array substrate in claim 7, wherein an oxygen hole content in the first etching barrier sections is greater than an oxygen hole content in the second etching barrier sections.

11. The array substrate in claim 7, wherein the metal oxide body layer comprises a plurality of first sections and a plurality of second sections, the first sections correspond to the first etching barrier sections, the second sections correspond to the second etching barrier sections, and an oxygen hole content in the first sections is greater than an oxygen hole content in the second sections.

12. The array substrate in claim 2, wherein materials of the metal oxide body layer and materials of the etching barrier layer are same.

13. The array substrate in claim 12, wherein a content of a zirconium element in the etching barrier layer is equal to or greater than a content of a zirconium element in the metal oxide body layer.

14. The array substrate in claim 2, wherein a ratio of a mass of a zirconium element in the etching barrier layer to a mass of all metal elements in the etching barrier layer ranges from 0.1% to 20%.

15. A manufacturing method of an array substrate, comprising following steps:
providing a substrate;
forming a metal light-shielding layer on the substrate;
forming a buffer layer on the metal light-shielding layer;
forming an active layer on the buffer layer, and the active layer comprising a metal oxide body layer and an etching barrier layer disposed on a surface of the metal oxide body layer away from the substrate, wherein the etching barrier layer comprises two first etching barrier sections disposed on a surface of the metal oxide body layer;
forming an interlayer insulating layer on the active layer;
patterning the interlayer insulating layer and the buffer layer to form a plurality of first via holes penetrating the interlayer insulating layer and a plurality of second via holes penetrating the interlayer insulating layer and the buffer layer; and
forming a source-drain electrode layer on the interlayer insulating layer, wherein the source-drain electrode layer is electrically connected to the first etching barrier sections through the first via holes, and the source-drain electrode layer is electrically connected to the metal light-shielding layer through the second via holes.

16. The manufacturing method of the array substrate in claim 15, wherein the step of patterning the interlayer insulating layer and the buffer layer comprises:
patterning the interlayer insulating layer and the buffer layer by a first mask, to form the plurality of first via holes penetrating the interlayer insulating layer and the plurality of second via holes penetrating the interlayer insulating layer and the buffer layer;
wherein the first mask comprises a plurality of first openings and a plurality of second openings, each of the first openings corresponds to one of the first via holes, each of the second openings corresponds to one of the second via holes, and the first openings and the second openings are fully light transmissive.

17. The manufacturing method of the array substrate in claim 15, wherein the step of forming the active layer on the buffer layer comprises:
forming the metal oxide body layer and the etching barrier layer on the buffer layer, wherein the etching barrier layer is disposed on the surface of the metal oxide body layer away from the substrate, the etching barrier layer comprises a plurality of metal oxide semiconductor materials doped with a zirconium element, and the etching barrier layer comprises the two first etching barrier sections disposed on the surface of the metal oxide body layer; and
annealing the active layer for at least 30 minutes at a temperature ranging from 150° C. to 220° C. in an air, to make at least part of the zirconium element in the etching barrier layer is present in a form of a microcrystalline zirconia.

18. A display panel, comprising an array substrate, the array substrate comprising:
a substrate;
a metal light-shielding layer disposed on a surface of the substrate;
a buffer layer disposed on a surface of the metal light-shielding layer away from the substrate;
an active layer disposed on a surface of the buffer layer away from the substrate;
an interlayer insulating layer disposed on a surface of the active layer away from the substrate and provided with a plurality of first via holes; and
a source-drain electrode layer disposed on a surface of the interlayer insulating layer away from the substrate and electrically connected to the active layer through the first via holes;
wherein the array substrate further comprises a plurality of second via holes penetrating the interlayer insulating layer and the buffer layer, the source-drain electrode layer is electrically connected to the metal light-shielding layer through the second via holes, the active layer comprises a metal oxide body layer and an etching barrier layer disposed on a surface of the metal oxide body layer away from the substrate, the etching barrier layer comprises a plurality of first etching barrier sections corresponding to the first via holes, and the source-drain electrode layer is electrically connected to the metal oxide body layer through the etching barrier layer.

19. The display panel in claim 18, wherein the etching barrier layer comprises a plurality of metal oxide semiconductor materials doped with a zirconium element, and doping elements of the metal oxide semiconductor materials comprise a microcrystalline zirconia.

20. The display panel in claim 19, wherein the metal oxide semiconductor materials comprise at least two metal oxide material layers, and metal oxide materials of two adjacent metal oxide material layers are different.
